(19) United States
(12) Patent Application Publication
(10) Pub. No.: US 2002/0185695 A1
(43) Pub. Date: Dec. 12, 2002

(54) Lateral DMOS structure with lateral extension structure for reduced charge trapping in gate oxide

(76) Inventor: James Douglas Beasom, Melbourne, FL (US)

Correspondence Address: Scott V Lundberg, Fogg Slifer & Polglaze PA, PO Box 581009, Minneapolis, MN, 55458-1009, US

(21) Appl. No.: 09/877,272

(22) Filed: Jun. 8, 2001

(51) Int. Cl. H01L 29/76

(52) U.S. Cl. 257/402; 257/342; 257/404; 257/409

(57) ABSTRACT

The present invention provides an improved lateral drift region for both bipolar and MOS devices where improved breakdown voltage and low ON resistance are desired. A top gate of the same conductivity type as the device region with which it is associated is provided along the surface of the substrate and overlying the lateral drift region. This top gate includes a higher doped region that does not deplete during reverse biasing. Because this region does not deplete the hot carriers flowing through it lose energy and therefore are less likely to be trapped by interface traps at the insulator oxide interface or in the bulk dielectric. Avoiding carrier trapping allows maintenance of a stable threshold voltage for the MOS device.

### FIELD OF THE INVENTION

The present invention relates generally to lateral semiconductor devices and specifically to high voltage lateral semiconductor devices with reduced ON resistance and a non-depletable extension region adjacent to the gate, and a method of making such devices.

Most commercial uses of power MOSFETs (metal-oxide-semiconductor field-effect transistors) use the MOSFET as an electronic switch. There are two key characteristics of a MOSFET when used in this power switching mode: its breakdown voltage and its ON resistance. The breakdown voltage is a measure of the MOSFET's ability to withstand voltage when it is in an OFF or open condition. The ON resistance is a measure of the resistance when the MOSFET is in an ON or closed condition. Improving the operation of the MOSFET switch suggests a breakdown voltage as high as possible and an ON resistance as low as possible. A perfect switching device has an infinite breakdown voltage and zero ON resistance.

Previous high voltage semiconductors configured as lateral elements include both MOS (metal-oxide-semiconductor) devices and bipolar junction transistors. See for example, commonly assigned U.S. Pat. Nos. 4,823,173 and 5,264,719, which are hereby incorporated by reference. For example, FIG. 1 illustrates a prior art high voltage lateral MOS device 8. The MOS device 8 includes a gate 10, a source 12 with p+ doping concentration and a drain 14, comprising a p+ region 14a formed in a p− shield region 14b. The MOS device 8 further includes a silicon dioxide (SiO₂) layer 13 overlying the various active regions as shown. A body 11 of the device 8 is doped n−. A drift region or drain extension 17 is doped p-type and extends along the top surface of the body 11, having one edge thereof adjacent to the p− shield region 14b. The drift region 17 forms a portion of the conducting path between the source 12 and the drain 14. A body contact 16 is also illustrated.

In operation, the gate 10 and the source 12 never reach large voltages relative to the body 11. The drift region 17 serves as a JFET (junction field-effect transistor) channel. A portion 11a of the body 11, underlying the drift region 17 provides a JFET gate function with respect to the drift region 17. The drift region 17 is designed to totally deplete (i.e., a pinch-off condition is created) when the drain/body junction 15 is reverse biased at a voltage lower than the voltage at which avalanche breakdown occurs in the p/n− junction between the drift region 17 and the body 11. The use of the depletable drift region 17 preserves the effective high breakdown voltage of the drain/body junction 15. The source 12 and the gate 10 are safely shielded from the high drain-body voltage by the pinched off depleted drift region 17.

The resistance of the drift region 17 is in series with the resistance of the channel 11b, consequently, the total ON resistance of the device 8 is simply the sum of these two individual resistances. The drift region 17, which must be quite long to sustain the high drain-source voltages, often contributes the larger of the two resistance terms. Thus, it is desirable to reduce the resistance of the drift region 17 so that MOSFET devices can be fabricated with lower total channel ON resistance.

FIG. 2 illustrates another prior art high voltage lateral MOS device 18. Devices such as the high-voltage lateral MOS device 18 are generally referred to as double-diffused MOS devices (DMOS) due to the diffusion of alternating nested dopant types in the body. Thus the channel length is not determined by the lithography of the gate but rather by the acceptor diffusion into the body and the subsequent donor diffusion into the acceptor well. The MOS device 18 includes a gate 19, an n+ drain contact 20, an n+ source 22 and a p+ body contact 24. Both the source region 22 and the body contact 24 are formed in a p− body shield region 26. A drift region 28, which serves as a drain extension, is an n− region extending along the top surface of the n− body 11, which operates as the drain. A conducting channel 32 lies below the gate 19, along the surface of the body shield region 26 between the n+ source 22 and the n− drift region 28. In this device, the n− drift region 28 must be lightly doped to obtain the high-voltage breakdown characteristics of a drain/body junction 33.

The ON resistance of the FIG. 2 lateral DMOS device 18 is approximately the sum of the ON resistance of the channel 32 and the resistance of the n− drift region 28 (essentially the bulk resistance). The lateral distance from the drain contact 20 to an edge 36 of the channel 32 must be long enough to provide sufficient length for the reverse bias depletion layer, which extends from the body-to-drain junction 33 into the lightly-doped drift region 28. This distance, recognizing that the n− substrate 11 has a relatively high resistivity, contributes to the high resistance in the drift region 28, which is often much greater than the resistance of the channel 32. Thus, again, it is desirable to reduce the drift region ON resistance of the FIG. 2 device.

FIG. 3 shows a prior art structure that can be used as a lateral bipolar junction transistor. The FIG. 3 device includes an n− base 39, an n-type emitter shield 40 formed therein, a p+ emitter 42 and a p+ collector 44 as shown. Additionally, a p− drift region 46 is provided along the top surface of the base 39, between the collector 44 and the emitter shield 40. In operation, the total collector resistance equals the sum of the resistance across the drift region 46 plus the resistance of the collector 44 between the drift region 46 and the collector contact, which is not shown in FIG. 3. To provide devices of equivalent size, having a lower collector resistance, it is desirable to reduce the resistance of the drift region 46.

In operation of the FIG. 3 device, the drift region 46 extends from one edge of the collector 44 to an edge of the emitter shield 40 so that the base width 41 is just the short distance between an edge 48 of the drift region 46 and an edge 49 of the emitter 42. Since the base width is relatively short, the device offers improved high-frequency response. At high base-to-collector voltages, the drift region 46 depletes by JFET action with the base 39 and the emitter shield 40 (which is effectively a part of the base), acting as a gate, while the collector 44 serves as the JFET drain. This depletion of the drift region 46 preserves the high voltage breakdown feature of the FIG. 3 device.

FIG. 4 illustrates yet another MOS prior art device having an n− body 50 and a p+ drain contact 51 formed in a p− shield region 52. The FIG. 4 device further includes an n+ body contact 54, a p+ source 56 and a gate 58. The MOS channel is designated by a reference character 60 in the n− body 50, below the gate 58. The FIG. 4 device further includes an n-type top gate 62 extending below the upper surface of the body 50 and formed within a p-type drift region 64. The resulting JFET comprises the n-type top gate 62 serving as the JFET top gate, the p-type drift region 64 serving as the JFET channel, the p− shield region 52 operating as the JFET drain, the MOS channel 60 serving the JFET source function, and the region 65 (which is within the n− body 50) forming the bottom gate. Note that the lateral or peripheral edge of both the top gate 62 and the drift region 64 extend to and preferably terminate at the edge 66, of the drain (i.e., the p− shield region 52).

The structure of FIG. 4 provides reduced ON resistance relative to the prior art MOS device shown in FIG. 1 above. The reduction in ON resistance is accomplished by providing a structure accommodating increased drift region doping (the drift region 64) without reducing the body-to-drain breakdown voltage. This is made possible by inclusion of the top gate 62. The depletion layer at the boundary between the top gate 62 and the drift region 64 holds some drift region charge when reverse biased, which is in addition to the charge held by the depletion layer between the region 65 and the drift region 64. This additional charge, in the form of fixed ionized impurity atoms, causes the channel resistance reduction. It is possible to provide approximately twice the doping level in the drift region 64 than previously acceptable due to this ability to hold drift region charge. The drift regions 64 of the prior art have an exemplary integrated doping of 1×10¹² boron atoms per square centimeter. Including the top gate 62 with an integrated doping of about 1×10¹² ions per square centimeter, a doping level of 2×10¹² boron atoms per square centimeter is possible in the drift region 64. Thus, the ON resistance in the FIG. 4 device is half the ON resistance of the prior structures.

To optimize performance of the FIG. 4 structure, the top gate 62 must be designed differently than a conventional JFET gate. The top gate 62 should become totally depleted at a body-to-drain voltage less than the breakdown voltage of the junction 66 between the top gate 62 and the p− shield region 52. Since the top gate 62 is in contact with the body 50 in the third dimension outside the plane shown in FIG. 4, the voltage at the junction 66 equals the voltage at the junction 53, and the breakdown voltage of the junction 66 should be greater than the voltage at which the top gate 62 totally depletes. Additionally, the top gate 62 should totally deplete before the depletion layer between the body 50 and the drift region 64 reaches the depletion layer between the top gate 62 and the drift region 64. This condition assures that a large voltage differential between the top gate 62 and the drain 51 is not developed by punch-through action from the body 50. As is known by those skilled in the art, an ordinary JFET gate (compared to the JFET action of the top gate 62) never totally depletes regardless of operating conditions.

Yet another embodiment of the prior art is illustrated in FIG. 5, which shows an LDMOS (lateral double-diffused metal-oxide-semiconductor) device having an n+ drain 80 and an n-type drift region or drain extension 92 formed along a top surface of a p− island 81. The FIG. 5 device includes an n+source 82 and a p+ body contact 84. Both the source 82 and the body contact 84 are formed in a p body shield region 86. The device channel region is designated by a reference character 88 below a gate 90. The device includes a JFET top gate region 96 disposed in the top surface of the drift region 92. Both the drift region 92 and the top gate 96 extend laterally beneath the gate 90. The separation between the top gate 96 and the drain 80 is formed by a mask alignment process.

Simulations of the FIG. 5 embodiment operated at a drain to source voltage high enough to totally deplete both the drift region 92 and the JFET top gate 96, reveal the paths along which the holes and electrons generated thermally and by avalanche multiplication flow through the depletion layer to the device terminals. In an NMOS device, holes separate into two paths along an approximately horizontal line running through the drift region 92. The holes below the line flow down into the undepleted p− island 81. The holes above the line flow up toward the depleted top gate 96 and then flow horizontally along the surface of the p− island 81 passing under the gate 90 and into the channel 88.

It is known that holes and electrons flowing through a region of high fields, such as the depleted region referred to above, gain energy and are therefore called hot carriers. Some of these hot carriers pass through and degrade the gate oxide and are then collected as gate current. Others become trapped in the gate oxide interface traps between the semiconductor and the insulator or within the oxide bulk. These additional fixed oxide charges affect operation of the device. Also, the barrier for hole injection into the valence band between silicon and silicon dioxide is higher than the barrier for injection of electrons into the conduction band. Trapped holes in the silicon dioxide provide a positive charge that reduces the threshold voltage. Trapped electrons increase the threshold voltage. If the shift in threshold voltage is large, the device ceases to properly function.

### BRIEF SUMMARY OF THE INVENTION

The above-mentioned undesirable trapping affects can be mitigated in accordance with the teachings of the present invention, which relates to a novel and an unobvious MOS device. According to the teachings of the present invention, the top gate of the drain extensions of a MOS device includes a section having an increased doping concentration that does not totally deplete. The holes flow through the top gate into the undepleted portion thereof, where they loose their energy during scattering events. This energy cannot be regained due to the absence of a high electric field in the nondepleted region. The holes then flow under the gate at a lower energy and into the p body. Because the holes (and electrons in a p-channel device) have significantly reduced energy in the region under the gate, there is a significantly reduced probability for trapping in interface traps or in the bulk silicon dioxide dielectric in that region.

### BRIEF DESCRIPTION OF THE DRAWINGS

The present invention can be more easily understood and the further advantages and uses thereof more readily apparent when considered in view of the description of the preferred embodiments and the following figures in which:

FIGS. 1 and 2 are cross-sectional views of prior art MOSFET devices;

FIG. 3 is a cross-sectional view of a prior art bipolar transistor;

FIGS. 4 and 5 are cross-sectional views of prior art MOSFET devices; and

FIGS. 6 and 7 are a cross-sectional views of MOS devices constructed according to the teachings of the present invention.

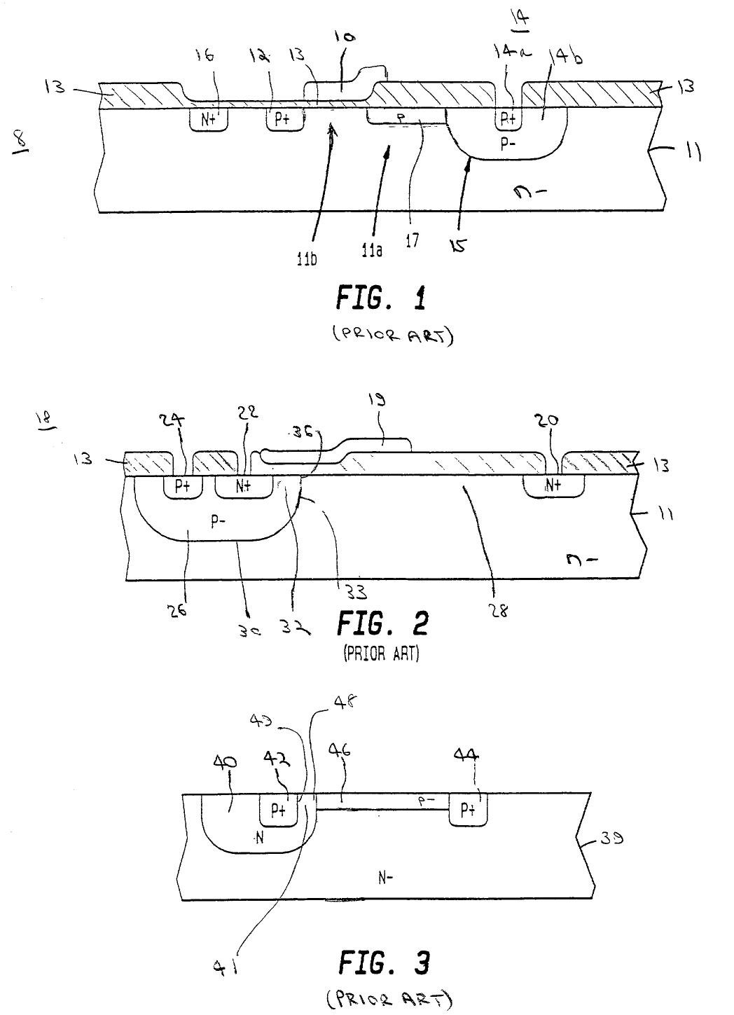

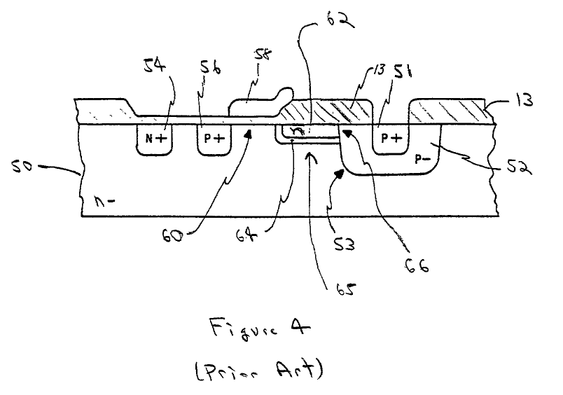

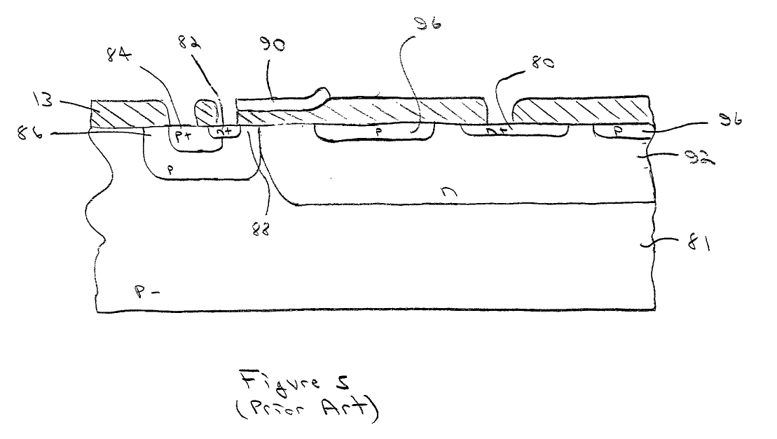

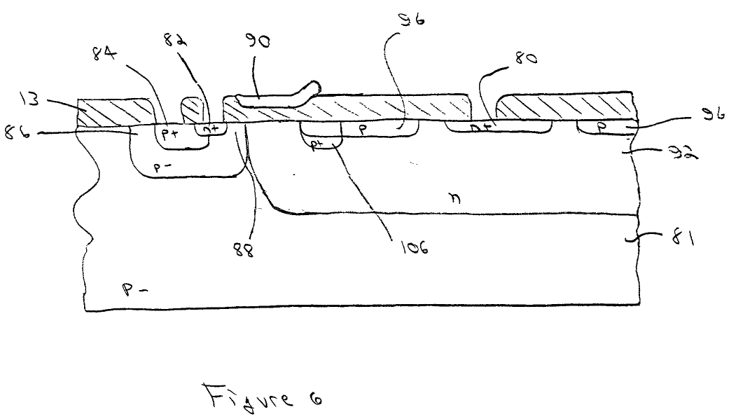

### DETAILED DESCRIPTION OF THE PREFERRED EMBODIMENTS

Before describing in detail the particular enhancements to the MOSFET device to reduce carrier trapping in accordance with the present invention, it should be observed that the present invention resides primarily in a novel combination of steps and elements related to an improved MOSFET structure, accordingly, the hardware components and method steps have been represented by conventional elements in the drawings, showing only those specific details that are pertinent to the present invention, so as not to obscure the disclosure with structural details that will be readily apparent to those skilled in the art having the benefit of the description herein.

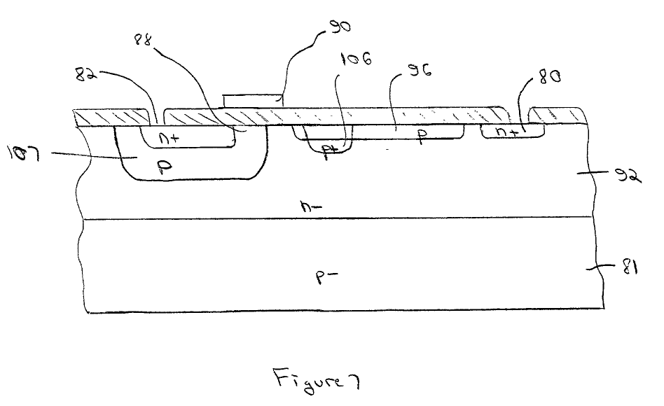

As discussed above, in an n-channel MOSFET it is desirable to avoid the threshold voltage reduction due to the holes trapped within the silicon dioxide and in the interface between the silicon dioxide and the semiconductor bulk material. (The effect is the same for electron carriers in a p− channel MOSFET.) These holes attract electrons, which induce an equivalent negative charge in the MOSFET body thereby lowering the threshold voltage. With reference to FIG. 6, therefore, the top gate 96 is augmented by a more highly doped p+ region 106 extending downwardly and partially into the drift region 92. The region 106 does not totally deplete during device operation, when the top gate 96 is depleted, and therefore as the holes flow through the drift region 92 into the non-depleting region 106, they lose energy during scattering events. As the holes leave the non-depleting region 106 and flow under the gate 90, they have a lower energy and therefore a reduced probability of being trapped in either interface traps or bulk dielectric traps.

The non-depleting region 106 does not degrade the breakdown voltage of the MOSFET device because it is operated at or near the voltage of the p− island 81. The gate 90 is also near the p− island voltage (typically within 20 volts). Thus, no high field region is generated in the area of the source 82.

Note that the non-depleting region 106 is separated from the drain 80 by the depletable top gate 96. The depletable characteristic of the top gate 96 prevents premature breakdown between the drain 80 and the non-depleting region 106.

The conductivity types illustrated for the various regions in FIG. 6, including the non-depleting region 106, can be reversed to form a PMOS device.

The non-depleting region 106 can be fabricated in several different ways. Extra doping can be introduced into the region adjacent to the gate 90 by a masked implant, adding to the doping of the top gate 96. The non-depleting region 106 can also be formed by a masked introduction of a layer used elsewhere in the process of fabricating the device, such as the p− body shield region 86 or the body contact 84. This latter process eliminates the need to introduce extra processing steps in the fabrication of the FIG. 6 device. The depth of the non-depleting region 106 is preferably shallow enough to not significantly increase the resistance of that portion of the drift region 92 below the non-depleting region 106.

An NMOS with a non-depleted portion has been simulated and optimized to have a voltage breakdown similar to a device structure having a totally depletable top gate 96. In this exemplary simulation, the length of the non-depletable portion was 1.5 microns. The non-depleting region 106 was formed by a masked implant of the same dose and energy used on the depleted top gate. The integrated dose for the depletable portion was reduced by approximately 20% compared to that used in the device with a total depleted top extension. In this simulation, the breakdown voltage for both the depletable and non-depletable versions was between 400V and 415V.

Another embodiment according to the teachings of the present invention is illustrated in FIG. 7. The device components bearing identical reference characters in FIGS. 6 and 7 serve identical functions. However, in FIG. 7 the drift region 92 is formed epitaxially on the p− substrate 81. Further, the source 82 is formed within a body region 107. The FIG. 7 embodiment functions identically to FIG. 6 wherein the top gate 96 includes the non-depleting region 106 that does not totally deplete during operation.

As is know by those skilled in the art there are many applications for such MOS devices as shown in FIG. 6. They can be used as linear switches in solid state relays and also in telecommunication switching circuits. In such applications two DMOS devices have their sources connected directly or through current limiting resistors and their drains serve as the output terminals of the switch. Further, photodiodes are built on the same chip and connected between the common gate and source to develop the voltage to turn on the devices. In this application a second metal layer is formed over the DMOS device to prevent light shining on to the photodiodes to develop the turn on voltage from inducing leakage current in the MOS device. Devices as shown in FIG. 6 can also be used in switching power supplies and as high voltage current sources.

While the invention has been described with reference to a preferred embodiment, it will be understood by those skilled in the art that various changes may be made and equivalent elements may be substituted for elements thereof without departing from the scope of the present invention. In addition modifications may be made to the teachings of the invention to adapt it to a particular situation, without departing from the essential scope thereof. Therefore, it is intended that the invention not be limited to the particular embodiment disclosed as the best mode contemplated for carrying out this invention but that the invention will include all embodiments falling within the scope of the appended claims.

What is claimed is:

1. A metal-oxide-semiconductor transistor comprising:
a semiconductor body of a first or a second conductivity type having a surface;
a pair of laterally spaced source and drain pockets of semiconductor material of a second conductivity type within said semiconductor body and adjoining the semiconductor body surface;
an extended drain region of the second conductivity type extending laterally in at least one direction away from said drain pocket and contiguous with the semiconductor body surface;
a top gate region within and forming a pn junction with said extended drain region and of the first conductivity type;
a higher-doped pocket of semiconductor material of the first conductivity type within said top gate region and having a higher integrated doping than said top gate region;
an insulating layer on the surface of said semiconductor body and covering at least that portion of the surface between said source pocket and the farthest edge, with respect to said drain pocket, of said extended drain region; and
a gate on said insulating layer and electrically isolated from said semiconductor body thereunder forming a channel laterally between said source pocket and the nearest point of said extended drain region, said gate electrode controlling, by field-effect, the flow of current thereunder through the channel.

2. The metal-oxide-semiconductor transistor of claim 1 wherein the top gate operates as a junction field-effect transistor gate that depletes during device operation while the higher-doped pocket remains undepleted.

3. The metal-oxide-semiconductor transistor of claim 1 wherein the extended drain region is a carrier drift region operating as a junction field-effect transistor channel.

4. The metal-oxide-semiconductor transistor of claim 1 wherein the doping concentration of the higher-doped pocket is established to avoid depletion in the higher-doped pocket.

5. The metal-oxide-semiconductor transistor of claim 1 wherein the integrated dose of the higher-doped pocket is about 2×10¹² ions/cm².

6. The metal-oxide-semiconductor transistor of claim 1 wherein the length of the higher-doped pocket is approximately 1.5 microns.

7. The metal-oxide-semiconductor transistor of claim 1 wherein the junction depth of the higher-doped pocket is less than the junction depth of the extended drain region.

8. The metal-oxide-semiconductor transistor of claim 1 wherein the higher-doped pocket is a region of the semiconductor body.

9. The metal-oxide-semiconductor transistor of claim 1 further comprising a contact of the first conductivity type for the semiconductor body, wherein said body contact adjoins the semiconductor surface.

10. The metal-oxide-semiconductor of claim 9 wherein the higher-doped pocket of semiconductor material of the first conductivity type has a doping profile substantially similar to the doping profile of the body contact.

11. The metal-oxide-semiconductor transistor of claim 1 further comprising a bipolar junction transistor, wherein the higher-doped pocket is formed as a region in the base of the bipolar junction transistor.

12. The metal-oxide-semiconductor transistor of claim 1 wherein the higher-doped pocket of semiconductor material is adjacent the gate.

13. An integrated MOS/JFET transistor device comprising an insulated gate field-effect transistor and a top and bottom gate junction field-effect transistor integrated in a semiconductor substrate, comprising a source region, and a drain region and a dual channel path formed in said semiconductor substrate between said source and said drain regions, said dual channel path comprising an insulated gate-controlled channel region having a first conductivity type in the presence of a channel inducing gate voltage, said insulated gate control channel region being contiguous with a top and bottom gate junction field-effect transistor channel region of the first conductivity type, and wherein said source region adjoins said insulated gate-controlled channel region and said drain region adjoins said top and bottom gate junction field-effect transistor channel region, and wherein a portion of said top and bottom gate junction field effect transistor top gate comprises a higher integrated doping than the remainder of said top and bottom gate junction field effect transistor top gate.

14. The integrated MOS/JFET transistor of claim 12 wherein the portion of the top and bottom gate junction field effect transistor top gate having the higher integrated doping does not totally deplete during device operation.

15. The integrated MOS/JFET transistor device of claim 12 wherein the portion of the top and bottom gate junction field effect transistor top gate having the higher integrated doping has an integrated doping of at least 2×10¹² ions/cm².

16. The integrated MOS/JFET transistor device of claim 12 wherein the portion of the top and bottom gate junction field effect transistor top gate having the higher integrated doping has an integrated doping of about 2×10¹² ions/cm².

17. The integrated MOS/JFET transistor device of claim 12 wherein the portion of the top and bottom gate junction field effect transistor top gate not having the higher integrated doping totally depletes before drain to body breakdown is reached.

18. A method of fabricating a metal-oxide semiconductor transistor in an integrated circuit, comprising:
forming laterally spaced source and drain pockets of a first conductivity type in the surface of a semiconductor body;
forming an insulator on the surface of the semiconductor body;
forming a gate on the insulator between the source and drain pockets and overlapping the source pocket;
forming an extended drain region of the first conductivity type in the surface of the semiconductor body, extending at least from the drain pocket to the nearest edge of the gate;
forming a top gate of a second conductivity type in the surface of the extended drain region such that a pn junction is formed with the extended drain region;
forming a portion of the top gate having a higher integrated doping.

19. The method of claim 18 wherein the extended drain has a net integrated doping of more than 1×10¹² ions per cm².

20. The method of claim 18 wherein the extended drain has a net integrated doping of about 2×10¹² ions per cm².

21. The method of claim 18 wherein the portion of the top gate not having higher integrated doping has a net integrated doping of about 1×10¹² ions per cm².

22. The method of claim 18 wherein the portion of the top gate having higher integrated doping has a net integrated doping of about 2×10¹² ions per cm².

23. The method of claim 18 wherein the portion of the top gate having higher integrated doping has a net integrated doping greater than 2×10¹² ions per cm².

24. The method of claim 18 further comprising the step of forming a semiconductor body region of the second conductivity type in the surface of the semiconductor body and containing the source pocket within the surface perimeter of the semiconductor body region of the second conductivity type.

25. The method of claim 24 wherein the dopant is introduced into the portion of the top gate having higher integrated doping and into the semiconductor body regions to form semiconductor bodies in the same dopant introduction step.

26. The method of claim 18 wherein the step of forming the portion of the top gate having higher integrated doping comprises a dopant introduction step common to the formation of other regions in the integrated circuit.

27. The method of claim 18 further comprising the step of forming a semiconductor body contact of the second conductivity type in the surface of the semiconductor body.

28. The method of claim 27 wherein the dopant is introduced into the portion of top gate having higher integrated doping and into the body contact region to form body contacts in the same dopant introduction step.

29. The method of claim 18 wherein the portion of the top gate having the higher integrated doping is adjacent an edge of the gate.
